(19) United States
(12) Patent Application Publication
(10) Pub. No.: US 2007/0037400 A1
(43) Pub. Date: Feb. 15, 2007

(54) Composition and methods removing polysilicon

(76) Inventors: Dong-Won Hwang, Suwon-si (KR); Hun-Jung Yi, Suwon-si (KR); Kwang-Shin Lim, Yongin-si (KR); Jung-Dae Park, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/495,706

(22) Filed: Jul. 31, 2006

(30) Foreign Application Priority Data
Aug. 11, 2005 (KR) 2005-73524

(51) Int. Cl. H01L 21/302; H01L 21/461

(52) U.S. Cl. 438/753; 438/689; 438/745

(57) ABSTRACT

Embodiments of the invention provide a composition adapted to remove polysilicon. The composition comprises about 1.0 to 10 percent by weight of alkylammonium hydroxide, about 0.1 to 5.0 percent by weight of hydrogen peroxide, and water.

### BACKGROUND OF THE INVENTION

1. Field of the Invention

Embodiments of the invention relate to a composition adapted to remove polysilicon and related methods. In particular, embodiments of the invention relate to a composition adapted to remove polysilicon, a method of removing polysilicon using the composition, and a method of manufacturing a semiconductor device using the composition.

This application claims priority to Korean Patent Application No. 2005-73524, filed on Aug. 11, 2005, the subject matter of which is hereby incorporated by reference in its entirety.

2. Description of the Related Art

The recent evolution of semiconductor devices is one characterized by constant demands for increased integration density and operating speed. Hence, many technical advances in fields related to the fabrication of semiconductor devices have been directed to increasing integration density and operation speed while ensuring overall reliability.

Polysilicon is one material widely used in the fabrication of semiconductor devices. For example, polysilicon is commonly used in the fabrication of gate electrodes, capacitor electrodes, plugs, etching masks, etc. Thus, an array of fabrication methods adapted to the formation, patterning, etching, and cleaning of polysilicon layers have been developed.

In general, a polysilicon layer is removed through either a dry etching process or a wet etching process. The dry etching process is performed using an etching gas in a plasma state. In particular, reactive materials such as ions or radicals react with a target in the dry etching process. In addition, a method of removing a polysilicon layer using the dry etching process has been developed. For example, a method of chemically dry etching a polysilicon layer using remote plasma is disclosed in Korean Laid-Open Patent Publication No. 2005-14440. In that method, a polysilicon layer is removed using a mixed etching gas, which comprises CF₄ gas and O₂ gas, and is removed with a high etching selectivity between the polysilicon layer and a silicon oxide layer and between the polysilicon layer and a silicon nitride layer. However, plasma having high energy is used in the dry etching process, and thus a semiconductor substrate and various structures formed around the polysilicon layer are readily damaged by the etching gas having high energy.

A wet etching process is a method of etching an object using a chemical etching solution. The wet etching process is performed by immersing an object to be etched into the etching solution. A solution comprising nitric acid and hydrofluoric acid has been conventionally used for etching a polysilicon layer. However, the solution comprising nitric acid and hydrofluoric acid removes the polysilicon layer with an excessively rapid etching rate, so the etching process cannot be readily controlled and an etching selectivity between polysilicon and silicon oxide is very low.

An etching solution comprising an alkali metal has been also developed for removing a polysilicon layer. For example, a method of removing an epitaxial silicon layer using an aqueous solution that comprises 40% of potassium hydroxide is disclosed in U.S. Pat. No. 4,056,413. The etching solution comprising an alkali metal has a rapid etching rate for polysilicon. However, the etching solution comprising an alkali metal also has disadvantages, such as poor uniformity of etching and surface roughness. Furthermore, when the alkali metal remains on a substrate after the etching process, a flat band shift is generated, and thus electrical characteristics of a semiconductor device are deteriorated.

A method for removing a polysilicon layer from a silicon wafer using an etching solution comprising ammonia water, hydrogen peroxide, and water is disclosed in Japanese Laid-Open Patent Publication No. 2001-156038. In this method, the etching solution comprises about 30 wt % ammonia water, about 30 wt % hydrogen peroxide solution and pure water by a weight ratio of about 5:1:500. An etching process is performed at a temperature of about 75° C.; however, ammonia water has a boiling point of about 36° C. under a normal pressure. Ammonia water is readily evaporated at the temperature of the etching process (i.e., about 75° C.); and thus, the concentration of ammonia water in the etching solution is reduced during the etching process. Therefore, the etching solution comprising ammonia water, which evaporates at the temperature at which the etching process is performed, has a greatly reduced etching ability and has the disadvantage of requiring ammonia water to be added to the etching solution during the etching process.

### SUMMARY OF THE INVENTION

Embodiments of the invention provide a composition adapted to remove polysilicon, wherein the composition has a higher concentration stability relative to a conventional composition and relatively high etching selectivity. Embodiments of the invention also provide a method of removing polysilicon using the composition, and a method of manufacturing a semiconductor device using the composition.

In accordance with embodiments of the invention, the ability of a composition adapted to remove polysilicon to remove polysilicon may be relatively stable because a concentration ratio of alkylammonium hydroxide to hydrogen peroxide may be constantly maintained in the composition. Furthermore, the composition may have a high etching selectivity between polysilicon and an oxide, and may selectively remove polysilicon through a wet etching process without damaging an oxide layer. Thus, the uniformity with which a polysilicon etching process etches polysilicon may be greatly improved.

In one embodiment, the invention provides a composition adapted to remove polysilicon comprising about 1.0 to 10 percent by weight of alkylammonium hydroxide, about 0.1 to 5.0 percent by weight of hydrogen peroxide, and water.

In another embodiment, the invention provides a method for removing polysilicon comprising removing a polysilicon workpiece by applying a composition comprising about 1.0 to 10 percent by weight of alkylammonium hydroxide, about 0.1 to 5.0 percent by weight of hydrogen peroxide, and water to the polysilicon workpiece.

In yet another embodiment, the invention provides a method of manufacturing a semiconductor device comprising forming an oxide layer on a substrate, forming a polysilicon layer on the oxide layer, and selectively removing the polysilicon layer using a composition comprising about 1.0 to 10 percent by weight of alkylammonium hydroxide, about 0.1 to 5.0 percent by weight of hydrogen peroxide, and water.

### BRIEF DESCRIPTION OF THE DRAWINGS

Embodiments of the invention will be described herein with reference to the accompanying drawings, in which like reference symbols refer to like or similar elements. In the drawings:

FIG. 1 is a flow chart illustrating a method of removing a polysilicon workpiece using a composition in accordance with an embodiment of the invention;

FIGS. 2 and 3 are cross-sectional views illustrating a method for fabricating a semiconductor device using a composition in accordance with an embodiment of the invention;

FIG. 4 is a graph showing, for the compositions prepared in Examples 1 and 2, the etching rate for a polysilicon layer and the etching rate for a silicon oxide layer;

FIG. 5 is a graph showing, for the compositions prepared in Examples 3 through 6, the etching rate for a polysilicon layer and the etching rate for a silicon oxide layer;

FIG. 6 is a graph showing an etching rate for a polysilicon layer of a composition prepared in Comparative Example 1;

FIG. 7 is a graph showing changes in the concentration of ammonium hydroxide and hydrogen peroxide, and the concentration ratio of ammonium hydroxide to hydrogen peroxide, in accordance with processing time in a composition prepared in Comparative Example 2; and,

FIG. 8 is a graph showing changes in the concentration of tetramethylammonium hydroxide and hydrogen peroxide, and the concentration ratio of tetramethylammonium hydroxide to hydrogen peroxide, in accordance with processing time in a composition prepared in Example 1.

### DESCRIPTION OF EMBODIMENTS

### Composition Adapted to Remove Polysilicon

In accordance with an embodiment of the invention, a composition adapted to remove polysilicon comprises about 1.0 to 10 percent by weight of alkylammonium hydroxide, about 0.1 to 5.0 percent by weight of hydrogen peroxide, and a remainder of water. As used herein, “percentage by weight” means percentage by weight based on the total weight of the resulting composition.

The alkylammonium hydroxide may react with the polysilicon to remove the polysilicon. The alkylammonium hydroxide comprises a hydroxyl group that is conventionally used for removing polysilicon, such as potassium hydroxide or ammonium hydroxide. The hydroxyl group of the alkylammonium hydroxide may react with the polysilicon to remove the polysilicon.

When a first composition comprises about 0.1 to 5.0 percent by weight of hydrogen peroxide, water, and less than about 1.0 percent by weight of alkylammonium hydroxide, the ability of the first composition to remove polysilicon may be greatly reduced relative to a composition in accordance with an embodiment of the invention. So, a polysilicon removal process using the first composition may take longer than a polysilicon removal process using a composition in accordance with an embodiment of the invention, and the first composition's etching selectivity between polysilicon and silicon oxide may be reduced relative to that of a composition in accordance with an embodiment of the invention. In addition, when a second composition comprises about 0.1 to 5.0 percent by weight of hydrogen peroxide, water, and greater than about 10 percent by weight of alkylammonium hydroxide, the rate at which the second composition etches polysilicon may be so high (i.e., fast) that the etching process (i.e., a process condition) may not be readily controlled. Therefore, a composition in accordance with an embodiment of the invention comprises about 1.0 to 10 percent by weight of alkylammonium hydroxide, and preferably about 1.5 to 8.0 percent by weight of alkylammonium hydroxide.

The alkylammonium hydroxide may be, for example, tetramethylammonium hydroxide, tetraethylammonium hydroxide, tetrapropylammonium hydroxide, tetrabutylammonium hydroxide, tetrahexylammonium hydroxide, tetraoctylammonium hydroxide, benzyltrimethylammonium hydroxide, diethyldimethylammonium hydroxide, hexadecyltrimethylammonium hydroxide, methyltributylammonium hydroxide, etc., or a combination thereof.

In one embodiment of the invention, the composition comprises tetramethylammonium hydroxide as the alkylammonium hydroxide.

The hydrogen peroxide in a composition comprising hydrogen peroxide may be adapted to adjust the rate at which the composition etches polysilicon. The hydrogen peroxide may reduce the reaction rate between the alkylammonium hydroxide and polysilicon. Thus, the ability of the composition to remove polysilicon may be controlled by changing the percentage by weight of hydrogen peroxide in the composition.

When a composition comprises about 1.0 to 10 percent by weight of alkylammonium hydroxide, water, and less than about 0.1 percent by weight of hydrogen peroxide, the etching rate of polysilicon may not be readily controlled. In addition, when a composition comprises about 1.0 to 10 percent by weight of alkylammonium hydroxide, water, and more than about 5.0 percent by weight of hydrogen peroxide, the composition's ability to remove polysilicon may be relatively greatly reduced, so a polysilicon removal process using the composition may take relatively longer and the composition's etching selectivity between polysilicon and silicon oxide may be reduced. Therefore, a composition in accordance with an embodiment of invention comprises about 0.1 to 5.0 percent by weight of hydrogen peroxide, and preferably about 0.1 to 1.0 percent by weight of hydrogen peroxide.

A composition in accordance with an embodiment of the invention also comprises water. The water may be, for example, pure water, ultra pure water, deionized water, distilled water, etc.

In one embodiment of the invention, the composition may have an etching selectivity between polysilicon and silicon oxide of at least about 5:1. In other words, the composition's etching rate for polysilicon may be at least five times greater than the composition's etching rate for silicon oxide. When a composition has an etching selectivity between polysilicon and silicon oxide that is less than about 5:1, undesired damage may be caused to a silicon oxide layer during a polysilicon etching process. Thus, a composition in accordance with an embodiment of the invention preferably has an etching selectivity between polysilicon and silicon oxide of at least about 5:1, and in particular has an etching selectivity between polysilicon and silicon oxide of at least about 100:1.

A composition in accordance with an embodiment of the invention may be prepared by mixing together alkylammonium hydroxide, hydrogen peroxide, and pure water using a stirrer or a circulation system.

A method for removing polysilicon using a composition in accordance with an embodiment of the invention and a method of manufacturing a semiconductor device using a composition in accordance with an embodiment of the invention will be described hereinafter.

### Method of Removing Polysilicon

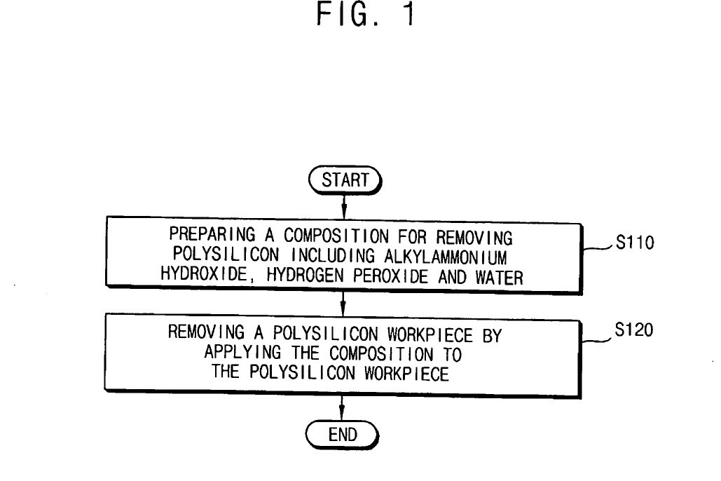

FIG. 1 is a flow chart illustrating a method for removing a polysilicon workpiece using a composition in accordance with an embodiment of the invention. The term “workpiece” in this context refers any portion of polysilicon material intended to be removed from a substrate, or an intervening layer formed on a substrate.

Referring to FIG. 1, a composition comprising about 1.0 to 10 percent by weight of alkylammonium hydroxide, about 0.1 to 5.0 percent by weight of hydrogen peroxide, and a remainder of water is prepared (step S110).

In particular, a composition in accordance with an embodiment of the invention, as described previously, may be prepared by mixing together alkylammonium hydroxide, hydrogen peroxide, and pure water using a stirrer or a circulation system.

Then, a polysilicon workpiece is removed by applying the composition to the polysilicon workpiece (step S120).

The polysilicon workpiece may be, for example, a polysilicon layer or a polysilicon structure formed on a lower structure. The lower structure may be, for example, a substrate, a substrate comprising an oxide layer, etc. The substrate may be, for example, a silicon wafer or a silicon-on-insulator (SOI) substrate.

When the composition is applied to the polysilicon workpiece, the alkylammonium hydroxide may react with the polysilicon to decompose polysilicon into substances that can be readily removed. As a result, the composition removes the polysilicon workpiece.

The composition may be applied to the polysilicon workpiece using a batch-type etching apparatus or a single-type etching apparatus.

The polysilicon workpiece may be removed at a temperature of about 55° C. to 90° C. When the temperature is lower than about 55° C., the polysilicon workpiece may not be completely removed, so a process for removing polysilicon may take relatively longer than at a sufficiently higher temperature. In addition, when the temperature is higher than about 90° C., an etching rate of polysilicon may not be readily controlled. Thus, the polysilicon workpiece may preferably be removed at a temperature of about 55° C. to 90° C., and in particular at a temperature of about 65° C. to 85° C.

A composition conventionally used for removing polysilicon comprises ammonium hydroxide and hydrogen peroxide. Ammonium hydroxide has a boiling point of about 36° C. under a normal pressure. When the etching process is performed at a temperature of about 55° C. to 90° C., ammonium hydroxide is readily evaporated so that the concentration of ammonium hydroxide in the composition is reduced. As used herein, “concentration” means percentage by weight. Thus, the conventional composition comprising ammonium hydroxide may have an ability to etch polysilicon that is lower than desired.

A composition in accordance with an embodiment of the invention, however, comprises alkylammonium hydroxide instead of ammonium hydroxide. Alkylammonium hydroxide has a boiling point that is substantially higher than the process temperature (i.e., the temperature at which the etching process is performed). Thus, a concentration ratio of alkylammonium hydroxide to hydrogen peroxide in the composition may be maintained relatively constantly, so the ability of the composition to etch polysilicon may be maintained at a satisfactory (i.e., good) level even after an etching process using the composition has been performed. As used herein, a “concentration ratio” of a first substance to a second substance is the ratio of the concentration of the first substance in a composition to the concentration of the second substance in the composition.

The polysilicon workpiece may be advantageously removed using a composition having an etching selectivity between polysilicon and silicon oxide that is greater than or equal to about 5:1. For example, the polysilicon workpiece may be removed using a composition having an etching selectivity between polysilicon and silicon oxide that is greater than or equal to about 100:1.

In accordance with an embodiment of the invention, the polysilicon workpiece may be selectively removed using a composition in accordance with an embodiment of the invention in which the composition has a high etching selectivity between polysilicon and silicon oxide, and a relatively high concentration stability. As used herein, “concentration stability” is a measure of how near to an initial concentration ratio a concentration ratio of components in a composition remained after an intervening event. In particular, a “relatively high concentration stability” means that a concentration ratio stays relatively near the initial concentration ratio.

A method for fabricating a semiconductor device using a composition in accordance with an embodiment of the invention will be described hereinafter.

### Method of Fabricating a Semiconductor Device

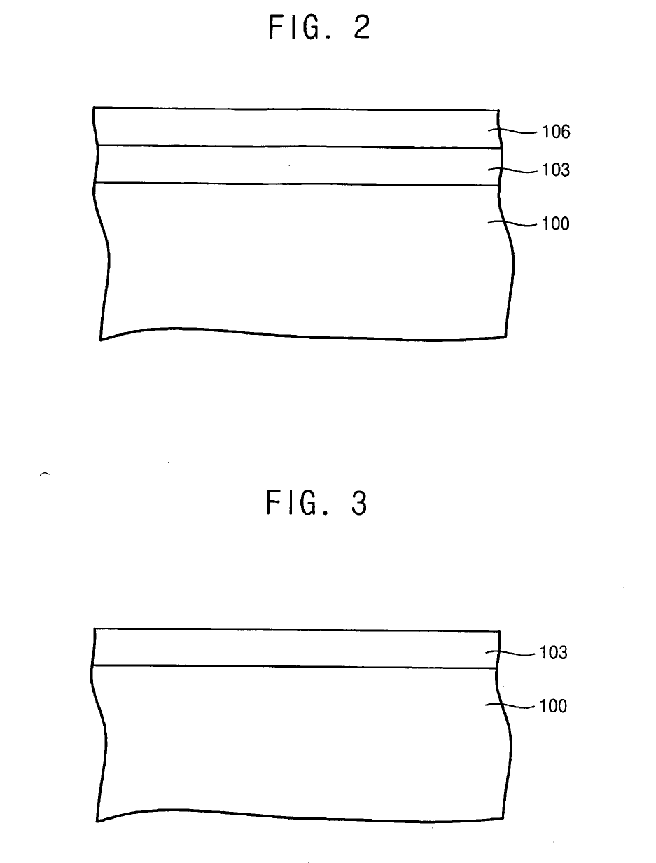

FIGS. 2 and 3 are cross-sectional views illustrating a method for fabricating a semiconductor device using a composition in accordance with an embodiment of the invention.

FIG. 2 is a cross-sectional view illustrating a substrate 100 after an oxide layer 103 and a polysilicon layer 106 have been successively formed on substrate 100.

Referring to FIG. 2, oxide layer 103 is formed on substrate 100. Substrate 100 may be, for example, a silicon wafer, a silicon-on-insulator (SOI) substrate, etc.

Oxide layer 103 may be formed using an oxide such as silicon oxide. Oxide layer 103 may be formed through a thermal oxidation process, a chemical vapor deposition process, an atomic layer deposition process, a high density plasma-chemical vapor deposition process, etc.

In one embodiment of the invention, oxide layer 103 may be a gate oxide layer of a high voltage transistor. Oxide layer 103 may be formed through a thermal oxidation process under an oxygen atmosphere. When the thermal oxidation process is performed at a temperature of less than about 700° C., an oxidation reaction that occurs may not be sufficient to form oxide layer 103. In addition, when the thermal oxidation process is performed at a temperature of greater than about 1,400° C., the semiconductor device being fabricated may be damaged by heat. Thus, the thermal oxidation process may be advantageously performed at a temperature of about 700° C. to 1,400° C. In one embodiment, for example, the thermal oxidation process is performed at a temperature of about 800° C. to 1,100° C. Oxide layer 103 thus formed may have a thickness-of about 500 Å to 2,000 Å.

Polysilicon layer 106 is formed on oxide layer 103. Polysilicon layer 106 may be formed through a chemical vapor deposition process. In particular, polysilicon layer 106 may be formed by thermally decomposing a gas comprising silane (SiH₄). The gas comprising silane may comprise, for example, about 100% silane gas or about 20% to 30% silane gas diluted by nitrogen gas.

When polysilicon layer 106 is formed at a temperature less than about 450° C., the rate at which polysilicon is deposited (i.e., a depositing rate of polysilicon) is excessively low. In addition, when the temperature is greater than about 650° C., the uniformity of polysilicon layer 106 may be reduced and the silane gas may be readily exhausted. Thus, polysilicon layer 106 may be advantageously formed at a temperature of about 450° C. to 650° C. When polysilicon layer 106 is formed at the temperature stated above, polysilicon layer 106 may be advantageously formed under a pressure of about 25 Pa to 150 Pa in accordance with a desired deposition rate (i.e., under a pressure of about 25 Pa to 150 Pa considering a depositing rate).

In accordance with an embodiment of the invention, when oxide layer 103 is adapted to be a gate oxide layer of a high voltage transistor, polysilicon layer 106 may prevent oxide layer 103 from being contaminated by impurities. For example, an isolation layer (not shown) may be formed on substrate 100 after oxide layer 103 and polysilicon layer 106 are formed on substrate 100. The isolation layer may be formed by successively forming a mask layer (not shown) and a photoresist pattern (not shown) on polysilicon layer 106; partially etching the mask layer, polysilicon layer 106, oxide layer 103, and substrate 100 to form a trench (not shown) in substrate 100; and filling the trench with an insulation material. When the isolation layer is formed through the processes described above, oxide layer 103 may be contaminated with impurities such as organic materials or metal. However, polysilicon layer 106 may prevent oxide layer 103 from being contaminated by the impurities.

After the isolation layer is formed in substrate 100, polysilicon layer 106 is removed and then a conductive layer (not shown) is formed on oxide layer 103. The conductive layer may serve as a gate electrode.

FIG. 3 is a cross-sectional view illustrating substrate 100 after polysilicon layer 106 has been removed from substrate 100.

Referring to FIG. 3, polysilicon layer 106 is removed by applying a composition in accordance with an embodiment of the invention onto substrate 100 on which oxide layer 103 and polysilicon layer 106 are formed.

Polysilicon layer 106 is removed using the composition, which comprises about 1.0 to 10 percent by weight of alkylammonium hydroxide, about 0.1 to 5.0 percent by weight of hydrogen peroxide, and a remainder of water. The composition has been described previously, so further description of the composition will be omitted here.

When the composition is applied to substrate 100 on which polysilicon layer 106 is formed, the alkylammonium hydroxide of the composition may react with the polysilicon of polysilicon layer 106 to decompose the polysilicon into substances that are readily removed. As a result, polysilicon layer 106 is removed from substrate 100.

In one embodiment, polysilicon layer 106 may be removed at a temperature of about 55° C. to 90° C. When polysilicon layer 106 is removed at a temperature of about 55° C. to 90° C., the process temperature may be equal to the temperature of the composition. The respective boiling points of the alkylammonium hydroxide and hydrogen peroxide are each relatively higher than the temperature of the composition, so a concentration ratio of alkylammonium hydroxide to hydrogen peroxide in the composition may be maintained relatively constantly. That is, as described above, the composition may have a relatively high concentration stability. Thus, the ability of the composition to etch polysilicon may be sustained at a satisfactory (i.e., good) level even after the process of removing polysilicon layer 106 has been performed.

In addition, polysilicon layer 106 may be removed from substrate 100 without damaging oxide layer 103. One disadvantage of damaging oxide layer 103 is that, when oxide layer 103 is a gate oxide layer of a high voltage transistor, for example, and oxide layer 103 is damaged during the process of removing polysilicon layer 106, operational failures may occur in the high voltage transistor. However, in accordance with an embodiment of the invention, polysilicon layer 106 may be advantageously removed with an etching selectivity between polysilicon layer 106 and oxide layer 103 of greater than or equal to about 5:1. In one embodiment of the invention, for example, polysilicon layer 106 is removed with an etching selectivity between polysilicon layer 106 and oxide layer 103 of greater than or equal to about 100:1. As a result, polysilicon layer 106 may be selectively removed from substrate 100 without substantially damaging oxide layer 103.

Additionally, substrate 100 may be rinsed using pure water to remove the composition and residual impurities from substrate 100 and oxide layer 103, and then substrate 100 may be dried to remove remaining pure water.

The method of removing the polysilicon layer 106 has been described previously, so further description of that method will be omitted here.

In accordance with an embodiment of the invention, polysilicon layer 106 may be selectively removed without substantially damaging oxide layer 103 using a composition having a relatively high concentration stability and a relatively high etching selectivity. Thus, a polysilicon layer may be etched more uniformly when using a composition in accordance with an embodiment of the invention than when using a conventional composition.

Embodiments of the invention will be described hereinafter with reference to exemplary compositions.

### Preparing Compositions Adapted for Removing Polysilicon

### EXAMPLE 1

Example 1 is a composition that was prepared by mixing about 5 percent by weight of tetramethylammonium hydroxide (TMAH), about 0.3 percent by weight of hydrogen peroxide, and a remainder of pure water.

### EXAMPLES 2 TO 6

Examples 2 through 6 are compositions that were prepared in substantially the same way as the composition prepared in Example 1, except for the percentage by weight of hydrogen peroxide or the percentage by weight of TMAH in each composition. Percentages by weight of components of the compositions of Examples 1 through 6, and Comparative Examples 1 and 2 are shown in Table 1.

### COMPARATIVE EXAMPLE 1

Comparative Example 1 is a composition that was prepared by mixing about 2 percent by weight of TMAH and a remainder of pure water.

### COMPARATIVE EXAMPLE 2

Comparative Example 2 is a composition that was prepared by mixing about 2 percent by weight of ammonium hydroxide, about 0.3 percent by weight of hydrogen peroxide, and a remainder of pure water.

TABLE 1

| | Hydroxide Compound | | Hydrogen Peroxide |
|---|---|---|---|
| | [wt %] | | [wt %] |
| Example 1 | TMAH | 5 | 0.3 |
| Example 2 | TMAH | 1 | 0.3 |
| Example 3 | TMAH | 5 | 0.5 |
| Example 4 | TMAH | 5 | 1.0 |
| Example 5 | TMAH | 5 | 1.5 |
| Example 6 | TMAH | 5 | 2.0 |
| Comparative | TMAH | 2 | — |
| Example 1 | | | |
| Comparative | Ammonium | 2 | 0.3 |
| Example 2 | Hydroxide | | |

### Evaluation of Etching Rate and Etching Selectivity

For each of the compositions prepared in Examples 1 through 6, the composition's etching rate for a polysilicon layer (i.e., the rate at which the composition etched a polysilicon layer) and the composition's etching rate for a silicon oxide layer (i.e., the rate at which the composition etched a silicon oxide layer) were evaluated.

For convenience of description, the evaluation process will be described herein with reference to the evaluation of the composition prepared in Example 1; however, each of the compositions prepared in Examples 2 through 6 was evaluated in the same way as the composition prepared in Example 1. To estimate the etching rate of the composition prepared in Example 1 for a polysilicon layer, a polysilicon layer was formed on a first silicon wafer through a chemical vapor deposition process. The chemical vapor deposition process was performed using a gas comprising about 100% silane gas at a temperature of about 600° C. and at a pressure of about 100 Pa. The polysilicon layer thus formed had a thickness of about 200 Å.

In addition, to estimate the etching rate of the composition prepared in Example 1 for a silicon oxide layer, a second silicon wafer was thermally oxidized at a temperature of about 900° C. to form a silicon oxide layer on the second silicon wafer. The thermal oxidation process was performed in an atmosphere of about 100% oxygen. The silicon oxide layer thus formed had a thickness of about 1,000 Å.

The respective etching processes for etching the polysilicon layer and for etching the silicon oxide layer were each performed using a batch-type etching apparatus. The composition prepared in Example 1 was maintained at a temperature of about 80° C. After the first silicon wafer on which the polysilicon layer was formed and the second silicon wafer on which the silicon oxide layer was formed had each been immersed in the composition prepared in Example 1, the thickness of the polysilicon layer and the thickness of the silicon oxide layer were each measured. The etching rate of the composition prepared in Example 1 for the polysilicon layer and the etching rate of the composition prepared in Example 1 for the silicon oxide layer were each then calculated from thickness changes in the respective layers in accordance with processing time. The etching rate of each of the compositions prepared in Examples 2 through 6 for a polysilicon layer and the etching rate of each of the compositions prepared in Examples 2 through 6 for a silicon oxide layer are shown in Table 2.

TABLE 2

| | Etching Rate for | Etching Rate for |
|---|---|---|
| | Polysilicon Layer | Silicon Oxide Layer |
| | [Å/min] | [Å/min] |
| Example 1 | 300 | 1.2 |
| Example 2 | 19.6 | 1.3 |
| Example 3 | 77 | 1.1 |
| Example 4 | 12.6 | 1.2 |
| Example 5 | 8.8 | 1.3 |
| Example 6 | 6.6 | 1.3 |

As shown in Table 2, each of the compositions prepared in Examples 1 through 6 removed a respective polysilicon layer with an etching rate of between about 6.6 Å/min and 300 Å/min. In addition, each of the compositions prepared in Examples 1 through 6 removed a respective silicon oxide layer with an etching rate of between about 1.1 Å/min and 1.3 Å/min. Thus, the results of Table 2 suggest that compositions in accordance with embodiments of the invention each have a substantially higher etching rate for removing a polysilicon layer than for removing a silicon oxide layer.

In addition, for each of the compositions prepared in Examples 1 through 6, the etching selectivity between a polysilicon layer and a silicon oxide layer was evaluated by comparing the etching rate for the polysilicon layer and the etching rate for the silicon oxide layer. The etching selectivity of a composition is defined as the ratio of the composition's etching rate for the polysilicon layer to the composition's etching rate for the silicon oxide layer. To find the etching selectivity of each of the compositions prepared in Examples 1 through 6, the ratio of the etching rate for the polysilicon layer to the etching rate for the silicon oxide layer was calculated for each of the compositions prepared in Examples 1 through 6. The etching selectivity of each of the compositions prepared in Examples 1 through 6 is shown in Table 3.

TABLE 3

| | Etching Selectivity |
|---|---|
| Example 1 | 250:1 |
| Example 2 | 15.1:1 |
| Example 3 | 70:1 |
| Example 4 | 10.5:1 |
| Example 5 | 6.77:1 |
| Example 6 | 5.1:1 |

As shown in Table 3, each of the compositions prepared in Examples 1 through 6 had an etching selectivity between about 5.1:1 and 250:1. Thus, the results of Table 3 suggest that a composition in accordance with an embodiment of the invention will remove a polysilicon layer with a relatively high etching selectivity between the polysilicon layer and a silicon oxide layer.

Etching rates and etching selectivities of compositions were evaluated in accordance with percentages by weight of alkylammonium hydroxide or hydrogen peroxide in the corresponding compositions using the results shown in Tables 2 and 3. Results of those evaluations will be described hereinafter.

### Evaluation of Etching Rate and Etching Selectivity in Accordance with Amount of Alkylammonium Hydroxide

Using the compositions prepared in Examples 1 and 2, the etching rate and etching selectivity of each composition was evaluated in accordance with the percentage by weight of alkylammonium hydroxide in the composition.

The compositions prepared in Examples 1 and 2 each comprised substantially the same amount of hydrogen peroxide, i.e., about 0.3 percent by weight. However, the compositions prepared in Examples 1 and 2 each comprised different percentages by weight of TMAH. In particular, the composition prepared in Example 1 comprised about 5 percent by weight of TMAH, and the composition prepared in Example 2 comprised about 1 percent by weight of TMAH. Each of the compositions prepared in Examples 1 and 2 were maintained at a temperature of about 80° C.

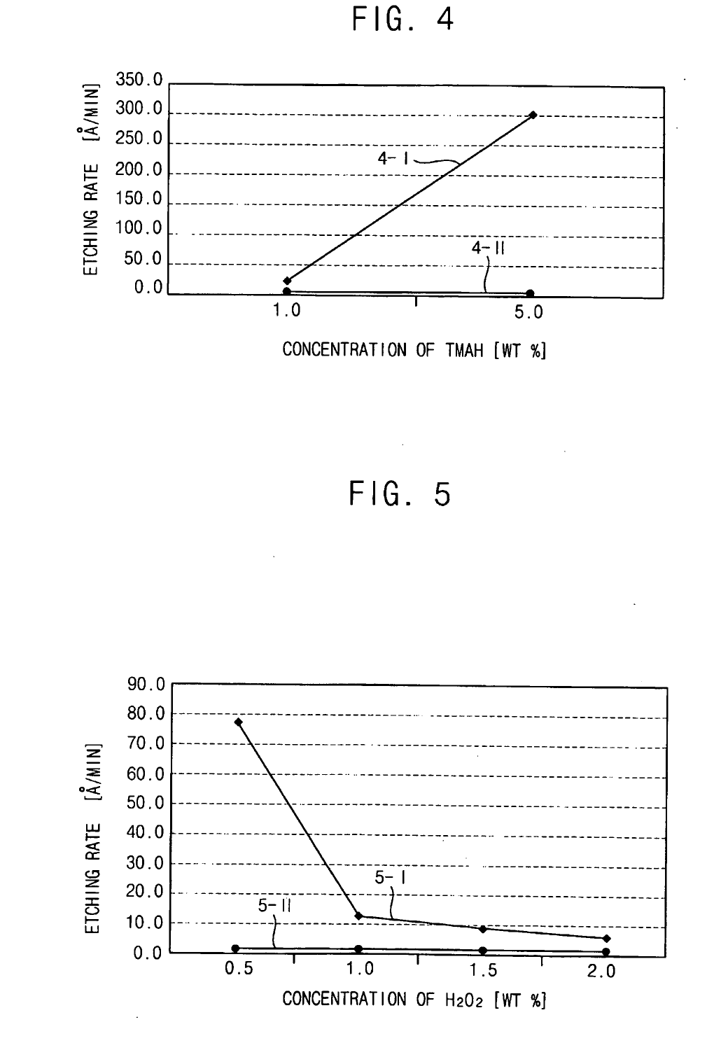

FIG. 4 is a graph showing, for each of the compositions prepared in Examples 1 and 2, the composition's etching rate for a polysilicon layer and the composition's etching rate for a silicon oxide layer. In FIG. 4, a first line 4-I shows etching rates for a polysilicon layer in accordance with the percentage by weight of TMAH in the compositions that correspond to the illustrated etching rates. A second line 4-II shows etching rates for a silicon oxide layer in accordance with the percentage by weight of TMAH in the compositions that correspond to the illustrated etching rates.

Referring to FIG. 4, the composition prepared in Example 1, which comprised 5 percent by weight of TMAH, had an etching rate for a polysilicon layer that was substantially higher than that of the composition prepared in Example 2, which comprised 1 percent by weight of TMAH. Thus, the preceding evaluation of Examples 1 and 2 suggests that a composition's etching rate for a polysilicon layer increases in accordance with an increase in the percentage by weight of alkylammonium hydroxide in the composition.

However, the compositions prepared in Examples 1 and 2 had similar etching rates for a silicon oxide layer. In particular, the compositions prepared in Examples 1 and 2 had etching rates of for a silicon oxide layer of about 1.2 Å/min to 1.3 Å/min. Thus, the preceding evaluation of Examples 1 and 2 also suggests that a composition's etching rate for a silicon oxide layer is not greatly altered in accordance with a change in the percentage by weight of alkylammonium hydroxide in the composition (i.e., suggests that the composition's etching rate for a silicon oxide layer does not depend greatly on the percentage by weight of alkylammonium hydroxide in the composition).

The composition prepared in Example 1, which comprised 5 percent by weight of TMAH had an etching selectivity substantially higher than that of the composition prepared in Example 2, which comprised 1 percent by weight of TMAH. In particular, the composition prepared in Example 1 had an etching selectivity of about 250:1 and the composition prepared in Example 2 had an etching selectivity of about 15.1:1. Thus, the preceding evaluation of Examples 1 and 2 also suggests that, for a composition used to remove a polysilicon layer, the composition's etching selectivity between the polysilicon layer and a silicon oxide layer increases in accordance with an increase in the percentage by weight of alkylammonium hydroxide in the composition.

### Evaluation of Etching Rate and Etching Selectivity in Accordance with Amount of Hydrogen Peroxide

Using the compositions prepared in Examples 3 through 6, the etching rate and etching selectivity of each composition was evaluated in accordance with the percentage by weight of hydrogen peroxide in the composition.

Each of the compositions prepared in Examples 3 through 6 comprised substantially the same amount of TMAH, i.e., about 5 percent by weight. However, the compositions prepared in Examples 3 through 6 each comprised different percentages by weight of hydrogen peroxide. In particular, the compositions prepared in Examples 3 through 6 comprised about 0.5 percent, about 1.0 percent, about 1.5 percent, and about 2.0 percent by weight of hydrogen peroxide, respectively. Each of the compositions prepared in Examples 3 through 6 were maintained at a temperature of about 80° C.

FIG. 5 is a graph showing, for each of the compositions prepared in Examples 3 through 6, the composition's etching rate for a polysilicon layer and the composition's etching rate for a silicon oxide layer. In FIG. 5, a first etching rate curve 5-I shows etching rates for a polysilicon layer in accordance with the percentage by weight of hydrogen peroxide in the compositions that correspond to the illustrated etching rates. A second etching rate curve 5-II shows etching rates for a silicon oxide layer in accordance with the percentage by weight of hydrogen peroxide in the compositions that correspond to the illustrated etching rates.

Referring to FIG. 5, the composition that comprised the least percentage by weight of hydrogen peroxide, i.e., the composition prepared in Example 3, had the highest etching rate for a polysilicon layer. As shown by first etching rate curve 5-I, for the compositions prepared in Examples 3 through 6, the lower the percentage by weight of hydrogen peroxide in a composition was, the lower was the composition's etching rate for a polysilicon layer. In particular, the composition comprising about 1.0 percent by weight of hydrogen peroxide (i.e., the composition prepared in Example 4) had a much lower etching rate for a polysilicon layer than did the composition comprising about 0.5 percent by weight of hydrogen peroxide (i.e., the composition prepared in Example 3). Thus, the preceding evaluation of Examples 3 through 6 suggests that a composition's etching rate for a polysilicon layer decreases in accordance with an increase in the percentage by weight of hydrogen peroxide in the composition, and that the composition's etching rate for a polysilicon layer may be controlled by changing the percentage by weight of hydrogen peroxide in the composition.

However, the compositions prepared in Examples 3 through 6 each had a similar etching rate for a silicon oxide layer. Particularly, the compositions prepared in Examples 3 through 6 each had an etching rate for a silicon oxide layer of between about 1.1 Å/min and 1.3 Å/min. Thus, the preceding evaluation of Examples 3 through 6 suggests that a composition's etching rate for a silicon oxide layer is not greatly altered in accordance with a change in the percentage by weight of hydrogen peroxide in the composition (i.e., suggests that the composition's etching rate for a silicon oxide layer does not depend greatly on the percentage by weight of hydrogen peroxide in the composition).

In addition, the composition prepared in Example 3, which comprised a relatively small amount of hydrogen peroxide, had an etching selectivity that was substantially higher than the respective etching selectivities of the compositions prepared in Examples 4 through 6, each of which comprised larger amounts of hydrogen peroxide relative to the composition prepared in Example 3. For example, the composition prepared in Example 3 had an etching selectivity of about 70:1, and the composition of Example 6 had an etching selectivity of about 5.1:1. Thus, the preceding evaluation of Examples 3 through 6 suggests that, when using a composition to remove a polysilicon layer, the composition's etching selectivity between a polysilicon layer and a silicon oxide layer increases in accordance with a decrease in the percentage by weight of hydrogen peroxide in the composition.

### Evaluation of Etching Rate in Accordance with Temperature

A composition's etching rate for a polysilicon layer was evaluated in accordance with the temperature of the composition using the composition prepared in Comparative Example 1.

Each polysilicon layer used to evaluate the above composition's etching rate for polysilicon was prepared through substantially the same process as the process described above by which each polysilicon layer was formed for evaluating etching rates for a polysilicon layer of the compositions prepared in Examples 1 through 6. The polysilicon layers were each etched for about 5 minutes using a composition prepared in Comparative Example 1. Etching processes were respectively performed on the polysilicon layers at respective temperatures of about 25° C., about 35° C., about 50° C., and about 70° C. The thickness of each polysilicon layer was measured after it had been etched, and the composition's etching rate for the polysilicon layer at each of the temperatures mentioned above was calculated in accordance with a change in thickness of a corresponding polysilicon layer in accordance with processing time.

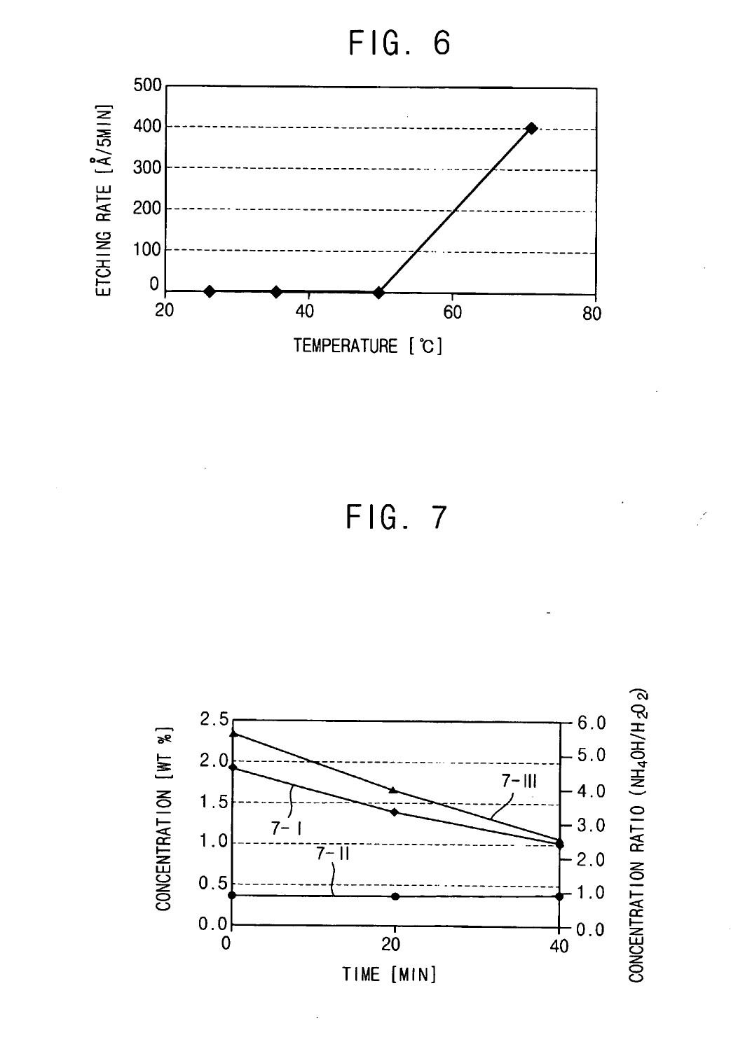

FIG. 6 is a graph showing the etching rates for a polysilicon layer of a composition in accordance with the temperature of the composition, wherein the composition was prepared in Comparative Example 1.

Referring to FIG. 6, the polysilicon layer was not readily etched at temperatures of about 25° C., about 35° C., or about 50° C., but the etching rate for the polysilicon layer was much greater at a temperature of about 70° C. relative to the previously mentioned temperatures. Thus, the preceding evaluation of Comparative Example 1 suggests that a composition comprising alkylammonium hydroxide and having a temperature greater than about 50° C. may etch a polysilicon layer. As a result, and in accordance with another consideration mentioned previously, a polysilicon layer may be advantageously removed at a temperature of about 55° C. to 90° C. using a composition comprising alkylammonium hydroxide.

### Evaluation of Concentration Stability of Composition

Concentration stabilities in accordance with processing time were evaluated using the compositions prepared in accordance with Comparative Example 2 and Example 1.

Etching processes were each performed at a temperature of about 80° C., and a concentration ratio between a hydroxide compound and hydrogen peroxide was measured. The composition prepared in accordance with Comparative Example 2 comprised ammonium hydroxide as the hydroxide compound, and the composition prepared in accordance with Example 1 comprised TMAH as the hydroxide compound.

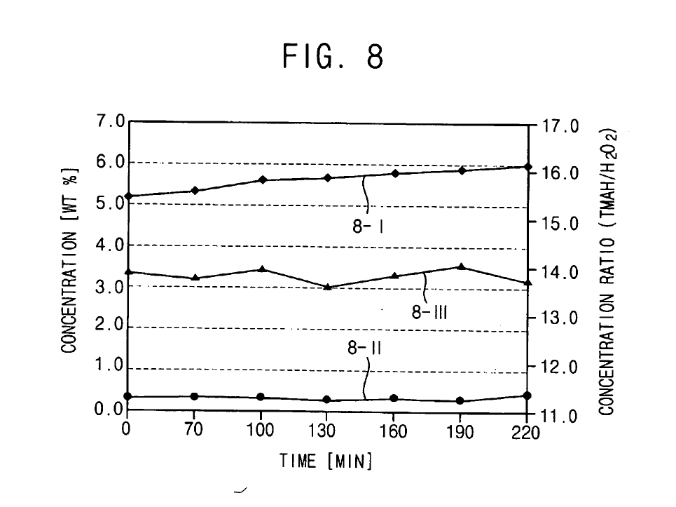

FIG. 7 is a graph showing variations in concentrations (i.e., percentages by weight) of ammonium hydroxide and hydrogen peroxide, and concentration ratios of ammonium hydroxide to hydrogen peroxide, each in accordance with a processing time for a composition prepared in accordance with Comparative Example 2. FIG. 8 is a graph showing variations in concentrations of TMAH and hydrogen peroxide, and concentration ratios of TMAH to hydrogen peroxide, each in accordance with a processing time for a composition prepared in accordance with Example 1. In FIGS. 7 and 8, first concentration curves 7-I and 8-I show concentrations of a hydroxide compound (in accordance with the vertical axis on the left side of the graphs of FIGS. 7 and 8, respectively), second concentration curves 7-II and 8-II show concentrations of hydrogen peroxide (in accordance with the vertical axis on the left side of the graphs of FIGS. 7 and 8, respectively), and third concentration curves 7-II and 8-III show concentration ratios of the hydroxide compound relative to hydrogen peroxide (in accordance with the vertical axis on the right side of the graphs of FIGS. 7 and 8, respectively).

Referring to FIG. 7, the concentration of hydrogen peroxide in the composition prepared in accordance with Comparative Example 2 increased slightly in accordance with the passage of processing time (see second concentration curve 7-II), but the concentration of ammonium hydroxide decreased by a relatively large amount in accordance with the passage of processing time (see second concentration curve 7-I). In addition, the concentration ratio of ammonium hydroxide to hydrogen peroxide decreased to less than half of its initial level in about 40 minutes. The decrease in the concentration ratio may be a result of ammonium hydroxide having a low boiling point of about 36° C. Ammonium hydroxide may be readily evaporated when the etching process is performed at about 80° C. Therefore, the ability of the composition to perform an etching process to etch polysilicon may be greatly reduced in accordance with relatively longer processing times (i.e., may be reduced in accordance with the passage of processing time). To perform an etching process using a composition comprising ammonium hydroxide, adding ammonium hydroxide to the composition during the etching process may be required. Alternatively, the composition comprising ammonium hydroxide may be used for a relatively short time and then discarded.

Referring to FIG. 8, the concentrations of TMAH and hydrogen peroxide in the composition prepared in accordance with Example 1 increased slightly in accordance with the passage of processing time (see first and second concentration curves 8-I and 8-II, respectively). When the etching process is performed at a temperature of about 80° C., a relatively small amount of water may be evaporated. However, the concentration ratio of TMAH to hydrogen peroxide was maintained at a relatively constant level even after the etching process was performed for about three hours. TMAH has a boiling point of about 102° C. and hydrogen peroxide has a boiling point of about 108° C. That is, the boiling points of TMAH and hydrogen peroxide are each substantially higher than the processing temperature, so the concentration ratio of TMAH to hydrogen peroxide may be maintained at a relatively constant level over the passage of processing time. As a result, a composition in accordance with an embodiment of the invention may have a greater concentration stability relative to a composition comprising ammonium hydroxide as the hydroxide compound and an excellent etching ability regardless of the passage of processing time.

In accordance with embodiments of the invention, a composition adapted to remove polysilicon may have an ability to etch polysilicon that remains relatively stable because a concentration ratio of an alkylammonium hydroxide to hydrogen peroxide may be maintained at a relatively constant level. Furthermore, the composition may have a high etching selectivity between polysilicon and an oxide, and may selectively remove polysilicon through a wet etching process without substantially damaging an oxide layer. Thus, when using a composition in accordance with an embodiment of the invention, the uniformity with which a polysilicon layer is removed may be greatly improved relative to when a conventional composition is used.

Although embodiments of the invention have been described herein, those skilled in the art will readily appreciate that modifications may be made to the embodiments without materially departing from the scope of the invention as defined by the accompanying claims.

What is claimed is:

1. A composition adapted to remove polysilicon comprising:
about 1.0 to 10 percent by weight of alkylammonium hydroxide;
about 0.1 to 5.0 percent by weight of hydrogen peroxide; and, water.

2. The composition of claim 1, comprising:
about 1.5 to 8.0 percent by weight of the alkylammonium hydroxide;
about 0.1 to 1.0 percent by weight of hydrogen peroxide; and, water.

3. The composition of claim 1, wherein the alkylammonium hydroxide comprises at least one substance selected from the group consisting of tetramethylammonium hydroxide, tetraethylammonium hydroxide, tetrapropylammonium hydroxide, tetrabutylammonium hydroxide, tetrahexylammonium hydroxide, tetraoctylammonium hydroxide, benzyltrimethylammonium hydroxide, diethyidimethylammonium hydroxide, hexadecyltrimethylammonium hydroxide and methyltributylammonium hydroxide.

4. The composition of claim 3, wherein the alkylammonium hydroxide comprises tetramethylammonium hydroxide.

5. A method, comprising:
removing a polysilicon workpiece by applying a composition comprising about 1.0 to 10 percent by weight of alkylammonium hydroxide, about 0.1 to 5.0 percent by weight of hydrogen peroxide, and water to the polysilicon workpiece.

6. The method of claim 5, wherein removing the polysilicon workpiece is performed at a temperature of about 55° C. to 90° C.

7. The method of claim 6, wherein removing the polysilicon workpiece is performed at a temperature of about 65° C. to 85° C.

8. The method of claim 5, wherein the polysilicon workpiece comprises a polysilicon layer formed on a lower structure.

9. A method of manufacturing a semiconductor device comprising:
forming an oxide layer on a substrate;
forming a polysilicon layer on the oxide layer; and, selectively removing portions of the polysilicon layer using a composition comprising about 1.0 to 10 percent by weight of alkylammonium hydroxide, about 0.1 to 5.0 percent by weight of hydrogen peroxide, and water.

10. The method of claim 9, wherein the oxide layer is formed using silicon oxide.

11. The method of claim 9, wherein selectively removing the polysilicon layer is performed at a temperature of about 55° C. to 90° C.

12. The method of claim 9, wherein the polysilicon layer is removed with an etching selectivity between the polysilicon layer and the oxide layer that is greater than or equal to about 5:1.

13. The method of claim 9, further comprising rinsing and drying the substrate.

14. The method of claim 9, wherein the oxide layer is formed through a thermal oxidation process, a chemical vapor deposition process, an atomic layer deposition process, or a high density plasma-chemical vapor deposition process.

15. The method of claim 14, wherein the oxide layer is formed through a thermal oxidation process.

16. The method of claim 15, wherein the thermal oxidation process is performed at a temperature of about 700° C. to 1,400° C.

17. The method of claim 16, wherein the thermal oxidation process is performed at a temperature of about 800° C. to 1,100° C.

18. The method of claim 15, wherein the oxide layer is a gate oxide layer of a high voltage transistor.

19. The method of claim 9, wherein forming the polysilicon layer comprises performing a chemical vapor deposition process.

20. The method of claim 9, wherein the polysilicon layer is formed at a temperature of about 450° C. to 650° C.
